(19) United States
(12) Patent Application Publication
(10) Pub. No.: US 2022/0398355 A1
(43) Pub. Date: Dec. 15, 2022

(54) DESIGN SUPPORT DEVICE AND STORAGE MEDIUM

(71) Applicant: Mitsubishi Electric Corporation, Tokyo (JP)

(72) Inventor: Naoya IDOTA, Tokyo (JP)

(73) Assignee: Mitsubishi Electric Corporation, Tokyo (JP)

(21) Appl. No.: 17/777,286

(22) PCT Filed: Jan. 20, 2020
(86) PCT No.: PCT/JP2020/001763

§ 371 Date: May 17, 2022

(51) Int. Cl. G06F 30/17

(52) U.S. Cl. CPC G06F 30/17

(57) ABSTRACT

A design support device includes a project data storage unit, a specification data storage unit, and a device profile generation unit. The project data storage unit stores project data including device information and monitoring information about a monitoring item, linked to the device information, the project data having information necessary for controlling a device. The specification data storage unit stores specification data in which a specification serving as a design guideline of a device profile is defined and an operated monitoring item name defined by a first calculation formula is included. Based on the project data, a device profile is generated, which include: device-monitoring item information having the monitoring information; and operation information by which a second calculation formula obtained from the first calculation formula using the monitoring item is associated with a label attached to a result of operation of the second calculation formula.

### FIELD

The present disclosure relates to a design support device, a design support method, and a design support program that support design of a factory automation (FA) system.

### BACKGROUND

In general, an FA system constituting a production line is realized by combining two or more kinds of devices including a machine tool. Then, these devices are realized not by only single-type vendors but by a combination of multiple-type vendors. When it is desired to monitor data of the devices in the FA system, it is necessary to develop an application for collecting data and displaying the collected data for each vendor. This has resulted in a problem that a displaying method has not been able to be standardized and also caused a significant amount of time and effort required for developing the application for each vendor. As a means for solving this problem, there is a device profile that is a file in which specifications different for each device are defined in a common format. That is, monitoring items are defined in advance as items desired to be monitored in a written specification that serves as a design guideline of the device profile, and the device profile is created by collecting data of a plurality of types of devices in accordance with the written specification. By creating the application using the device profile, there is no need to prepare the application for each vendor, and even a single application can collect the data of the plurality of types of devices and display the collected data.

Patent Literature 1 discloses a programmable logic controller (PLC) system specification creation supporting device that supports creation of hardware and software specifications for a PLC system that controls a machine with use of a PLC. In the technique described in Patent Literature 1, a management item table database is created, in which with respect to management items, a PLC station number for identifying a PLC and input and output signals related to the control or input and output signals related to the monitoring are defined. From the management item table database, a PLC configuration table and a PLC input and output table are automatically generated, the PLC configuration table being set to make arrangement of a central processing unit (CPU) device and input and output devices which constitute the PLC system, and the PLC input and output table being set to associate terminals of the input and output devices with addresses in the CPU device.

### CITATION LIST

### Patent Literature

Patent Literature 1: Japanese Patent Application Laid-open No. 2017-191429

### SUMMARY

### Technical Problem

However, in a case where the PLC input and output table generated by the technique described in Patent Literature 1 is used as a device profile, one can monitor only a monitoring item associated with the input and output signals related to a single category of control or the input and output signals related to a single category of monitoring. For example, in a case where it is desired to monitor an item indicated by a calculation formula including one or more monitoring items and one or more operators, there has been a problem that the calculation formula needs to be manually inputted, by a user, to a program for collecting data and displaying the collected data.

The present disclosure has been made in view of the above circumstances, and an object of the present disclosure is to provide a design support device that can generate a device profile without relying on any manual work of a user, the device profile including an item indicated by a calculation formula that includes one or more monitoring items and one or more operators.

### Solution to Problem

In order to solve the above problem and achieve the object, the present disclosure provides a design support device comprising: a project data storage unit to store project data including device information that is information about a device and monitoring information that is information about a monitoring item and is linked to the device information, the project data having information necessary to control the device, stored therein; a specification data storage unit to store, therein, specification data that is data in which a specification serving as a design guideline of a device profile is defined, and includes an operated monitoring item name defined by a first calculation formula; and a device profile generation unit to generate a device profile including device-monitoring item information and operation information on the basis of the project data, the device-monitoring item information having a description of the monitoring information according to a common format that is not dependent on the device, and the operation information having an association of a second calculation formula obtained by modifying the first calculation formula using the monitoring item of the project data, with a label attached to a result of operation of the second calculation formula.

### Advantageous Effects of Invention

The design support device according to the present disclosure has an advantageous effect that it can generate the device profile without relying on manual work of a user, the device profile including the item indicated by the calculation formula that includes one or more monitoring items and one or more operators.

### BRIEF DESCRIPTION OF DRAWINGS

FIG. 1 is a block diagram schematically illustrating an example of a configuration of a design support device and an FA system according to a first embodiment.

FIG. 2 is a table illustrating an example of contents of specification data according to the first embodiment.

FIG. 3 is a table illustrating an example of contents of specification data according to the first embodiment.

FIG. 4 is a table illustrating an example of a configuration of project data according to the first embodiment.

FIG. 5 is a diagram illustrating an example of a configuration of a device profile according to the first embodiment.

FIG. 6 is a diagram illustrating an example of a calculation formula setting screen according to the first embodiment.

FIG. 7 is a diagram illustrating an example of a configuration of the device profile including an operated monitoring item based on a calculation formula according to the first embodiment.

FIG. 8 is a diagram illustrating another example of the calculation formula setting screen according to the first embodiment.

FIG. 9 is a flowchart illustrating an example of a procedure of a design support method according to the first embodiment.

FIG. 10 is a table illustrating another example of the project data according to the first embodiment.

FIG. 11 is a diagram illustrating another example of the device profile according to the first embodiment.

FIG. 12 is a table illustrating an example of a configuration of project data according to a second embodiment.

FIG. 13 is a diagram illustrating an example of a configuration of a device profile according to the second embodiment.

FIG. 14 is a flowchart illustrating an example of a procedure of a design support method according to the second embodiment.

FIG. 15 is a table illustrating an example of a configuration of project data according to a third embodiment.

FIG. 16 is a diagram illustrating an example of a configuration of a device profile according to the third embodiment.

FIG. 17 is a diagram illustrating an example of a calculation formula setting screen according to a fourth embodiment.

FIG. 18 is a diagram illustrating an example of a device profile according to the fourth embodiment.

FIG. 19 is a flowchart illustrating an example of a procedure of a design support method according to the fourth embodiment.

FIG. 20 is a block diagram schematically illustrating an example of a configuration of a design support device and an FA system according to a fifth embodiment.

FIG. 21 is a diagram illustrating an example of the configuration of the design support device and the FA system according to the fifth embodiment.

FIG. 22 is a flowchart illustrating an example of a procedure of a design support method according to the fifth embodiment.

FIG. 23 is a diagram illustrating an example of a screen of a display unit of the design support device according to the fifth embodiment.

### DESCRIPTION OF EMBODIMENTS

Hereinafter, a design support device, a design support method, and a design support program according to embodiments of the present disclosure will be described in detail with reference to the drawings. Note that the present disclosure is not necessarily limited by these embodiments.

### First Embodiment

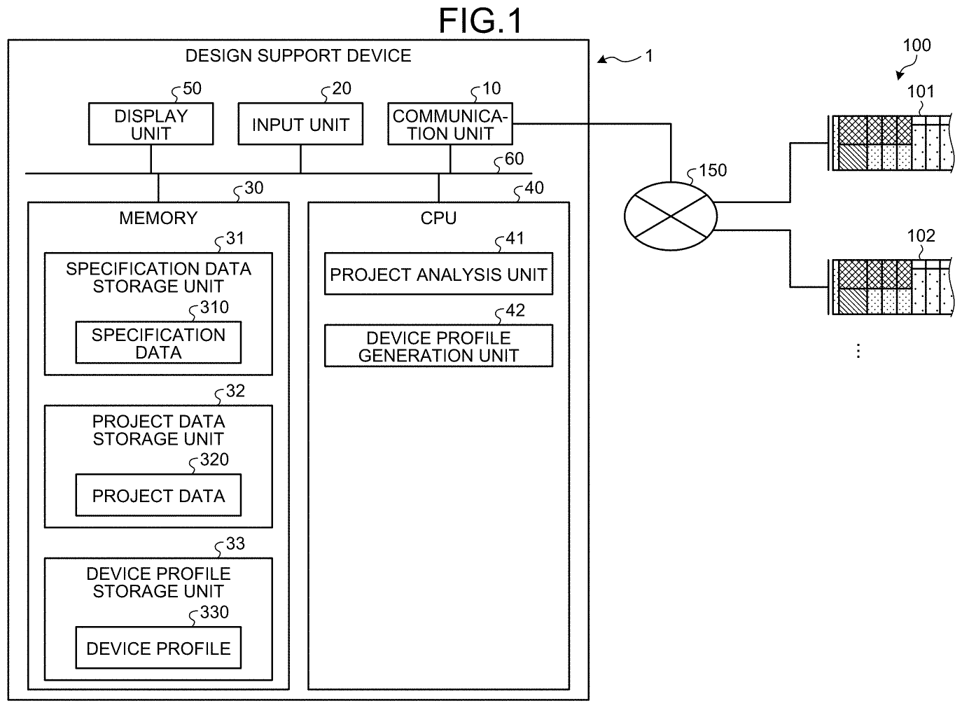

FIG. 1 is a block diagram schematically illustrating an example of a configuration of a design support device and an FA system according to a first embodiment. A design support device 1 as an engineering tool is connected to an FA system 100 via a network 150.

The FA system 100 includes devices 101 and 102. Specific examples of the devices 101 and 102 are machine tools such as a laser processing machine, a rotary cutter, a conveyor, and a packaging machine. The FA system 100 is constituted by a plurality of the devices 101 and 102, and the number of the devices 101 and 102 that constitute the FA system 100 is not limited. Furthermore, the devices 101 and 102 each include two or more subdevices. A specific example of the subdevice is a PLC.

The design support device 1 includes a communication unit 10, an input unit 20, a specification data storage unit 31, a project data storage unit 32, a project analysis unit 41, a device profile generation unit 42, a device profile storage unit 33, and a display unit 50.

The communication unit 10 communicates with the FA system 100 via the network 150. The input unit 20 is a user interface that receives an input from a user. A user inputs, via the input unit 20, device information that is information about the devices 101 and 102 constituting the FA system 100. The inputted device information is written into project data 320 in the project data storage unit 32. The device information is information related to data outputted from the device or control data for controlling the device, and includes device memory information. The device memory information includes a device name that is a name indicating an area of a shared memory of the subdevices constituting the device, and a data type indicating a type of data of a device value stored in the area. The shared memory stores the data outputted from the device or the control data for controlling the device. Specific examples of the data type include time, a word [signed], a word [unsigned], a bit string, a double word [unsigned], and the like.

Moreover, a user can set route information in the project data 320 via the input unit 20, the route information indicating a connection configuration between the design support device 1 and each of the devices constituting the FA system 100.

Then, the user can link, via the input unit 20, the device information of the devices constituting the FA system 100 to monitoring information that is information about a monitoring item of the device to be included in a device profile 330. Specifically, a user links the above-mentioned device information to the above-mentioned monitoring information within the same record in a list form via the input unit 20, thereby to write the resultant into the project data 320. The project data 320, which is data including the device information and the monitoring information linked to each other in a list form, is stored in the project data storage unit 32. Specific examples of the monitoring item include items such as an amount of electric power consumed by the device and a mean time to failure of the device.

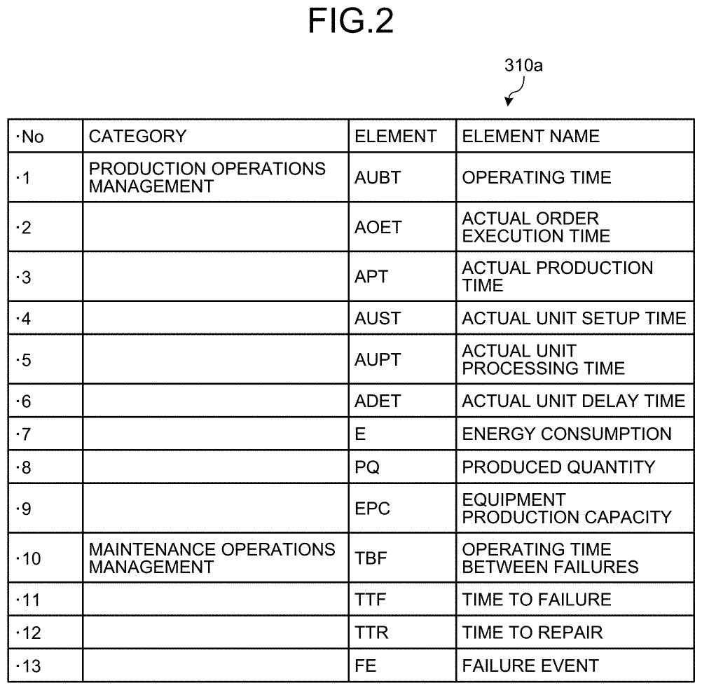

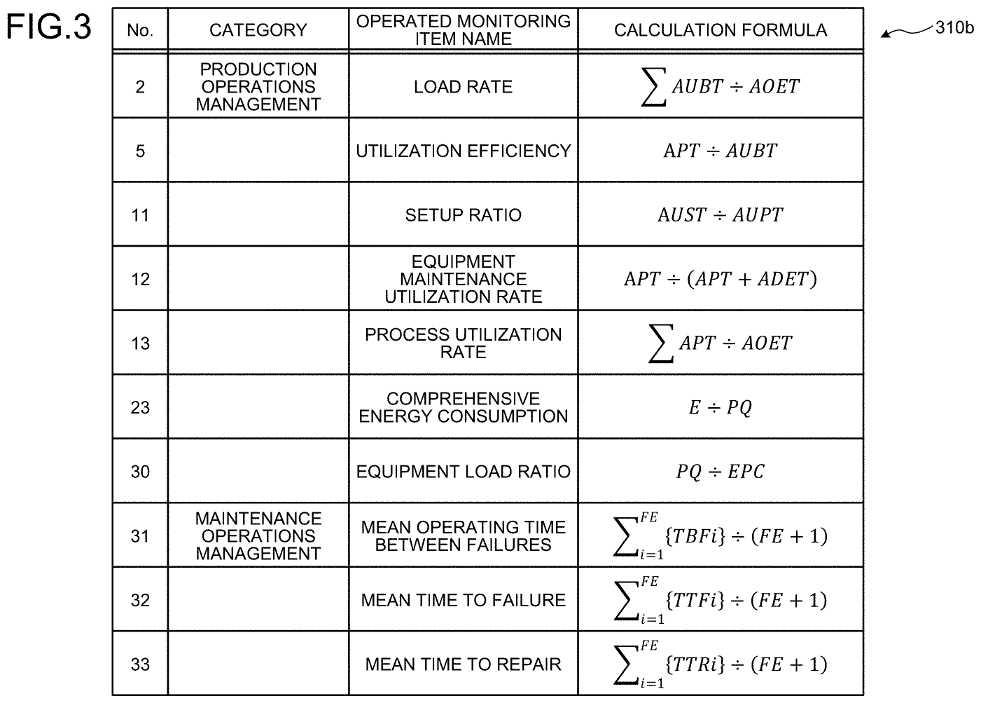

The specification data storage unit 31 stores specification data 310 that is data in which specifications serving as a design guideline of the device profile 330 are defined. In the specification data 310, as an example, monitoring details for the FA system 100 are defined. FIGS. 2 and 3 are tables each illustrating an example of contents of the specification data according to the first embodiment.

In specification data 310a of FIG. 2, for each category, what are defined are a constituent element indicating contents of data acquired from a subdevice of the FA system 100 necessary for performing management indicated by the category, and a constituent element name that is a name given to the element. The category includes, as examples, production operations management, maintenance operations management, and the like. The element indicates a superordinate concept of the monitoring items to be described later. That is, the element includes the monitoring item. It can be said that the specification data 310a has general classification of the monitoring items provided therein.

In specification data 310b of FIG. 3, for each category, there are defined a calculation formula created using one or more monitoring items and one or more operators necessary for performing management indicated by the category, and an operated monitoring item name that is a name given to a result of operation using the calculation formula. The category is similar to that in FIG. 2. The operated monitoring item name is the name given to content of the operation using the calculation formula in which one or more monitoring items and one or more operators are combined. The operator is a mathematical symbol indicating that a predetermined operation is to be performed and is, as an example, an operator indicating any of four basic arithmetic operations. For example, in the production operations management, when it is desired to monitor “allocation ratio” that is an operated monitoring item name, one just has to acquire “AUBT” and “AOET” as the elements with reference to the calculation formula and calculate “EAUBT÷AOET” that is the calculation formula in question. The monitoring item is an item specified in the project data 320, and is set to specify the content of the element of FIG. 2 in further detail. As an example, the monitoring item is a value of the element at a certain time. The calculation formula specified in the specification data 310b corresponds to a first calculation formula.

Returning to FIG. 1, the project data storage unit 32 stores the project data 320. The project data 320 is data having information necessary for controlling the devices 101 and 102 constituting the FA system 100 stored therein. In addition to causing the information about the devices 101 and 102 as described below to be included in the project data 320, the project data 320 can include a control program for controlling the devices 101 and 102 and network analysis information such as connection information or route information between the devices 101 and 102 and other devices.

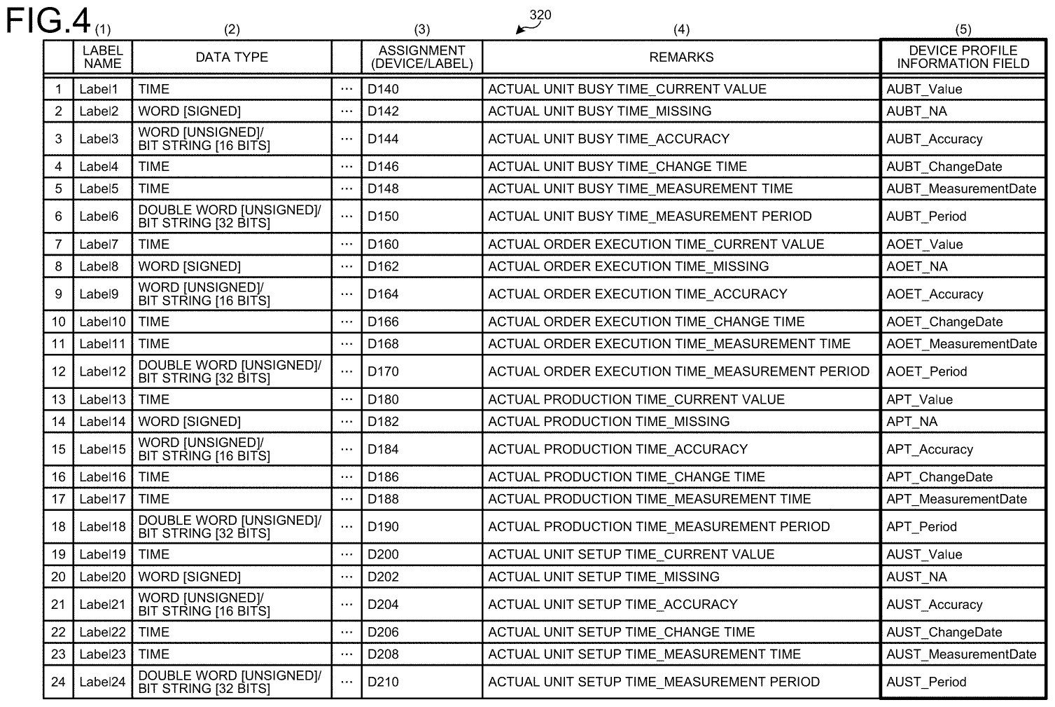

FIG. 4 is a table illustrating an example of a configuration of the project data according to the first embodiment. FIG. 4 illustrates a state in which the project data 320 is displayed on the display unit 50. FIG. 4 displays a part of the project data 320, and the project data 320 also includes the control program for the corresponding device and the like.

The project data 320 corresponds to one device and includes information of subdevices constituting the device in a list form. That is, the project data 320 includes information on each of the subdevices used to compose the device as the corresponding device information, and the information on each subdevice includes device memory information. Each record of the project data 320 in a list form corresponds to each row of FIG. 4. One record is formed of a plurality of fields. The name of the field is a field name.

As illustrated in FIG. 4, in the project data 320, fields corresponding to field names of “label name”, “data type”, “assignment (device/label)”. “remarks”, and “device profile information field” are set in each record. In the field corresponding to “label name”, there is stored identifier information of each record such as an arbitrary label or tag obtained by an input of a user or by other means. In the field corresponding to “data type”, there is stored a data type of the device memory information. In the field corresponding to “assignment (device/label)”, there is stored a device name of the device memory information. In the field corresponding to “remarks”, there is stored information of a comment of a user. The field corresponding to “device profile information field” is a link information storage area, in which monitoring information is stored. The link information storage area is linked to the device information, and thus a user can link between the monitoring information and the device information in the same record by storing, in the link information storage area, the monitoring information that is information on the monitoring item to be included in the device profile 330.

The specification data 310a in FIG. 2 indicates the element, such as “AUBT” representing “operating time”, that corresponds to a general superordinate concept of the monitoring item. With reference to the element indicated by the specification data 310a illustrated in FIG. 2, a user stores specific monitoring information to be included in the device profile 330 in the link information storage area. The monitoring information has specific contents such as “AUBT_Value” indicating information about a monitoring item “operating time_current value”. A user can further store the “operating time_current value” that is the name of the monitoring item, in the field corresponding to the “remarks”.

When a user stores the monitoring information to be included in the device profile 330 in the link information storage area that is the field corresponding to the “device profile information field”, the device information and the monitoring information are liked to each other in a record including the link information storage area. When it is specifically explained, in a record in which the “label name” is “Label1”, “time” that is the data type of the device memory information and “D140” that is the device name of the device memory information are linked to “AUBT_Value” that is the monitoring information, and the linked result is stored in the project data 320.

A user may store the monitoring information in the link information storage area of the project data 320 by a method in which the user inputs characters via the input unit 20, or a method in which the user makes a selection from candidates of the monitoring information displayed in a selective manner using a drop-down list or the like. That is, the input unit 20 may receive the monitoring information to be stored in the project data 320 as a character input from the user or may receive it as a selection input from the user. As described above, the user is allowed to create the project data 320 when designing the FA system 100 on the design support device 1.

Returning to FIG. 1, the project analysis unit 41 analyzes the project data 320 held in the project data storage unit 32, extracts information to be used in the device profile 330, and outputs the extracted information to the device profile generation unit 42. As described above, the project data 320 includes information such as the control program besides those in the fields illustrated in FIG. 4. Therefore, the project analysis unit 41 extracts information in the fields corresponding to the “label name”, “data type”, “assignment (device/label)”, “remarks”, and “device profile information field” to be used for creating the device profile 330 from the project data 320.

The device profile generation unit 42 generates the device profile 330 by mapping data of these extracted information pieces outputted from the project analysis unit 41 in accordance with the format of the device profile 330. At the time of this mapping, the device profile generation unit 42 generates the device profile 330 by utilizing a reality of the situation in which the device information and the monitoring information are linked to each other. Note that the device profile 330 includes various types of information, and information in which the device information and the monitoring information are linked is hereinafter also referred to as device-monitoring item information.

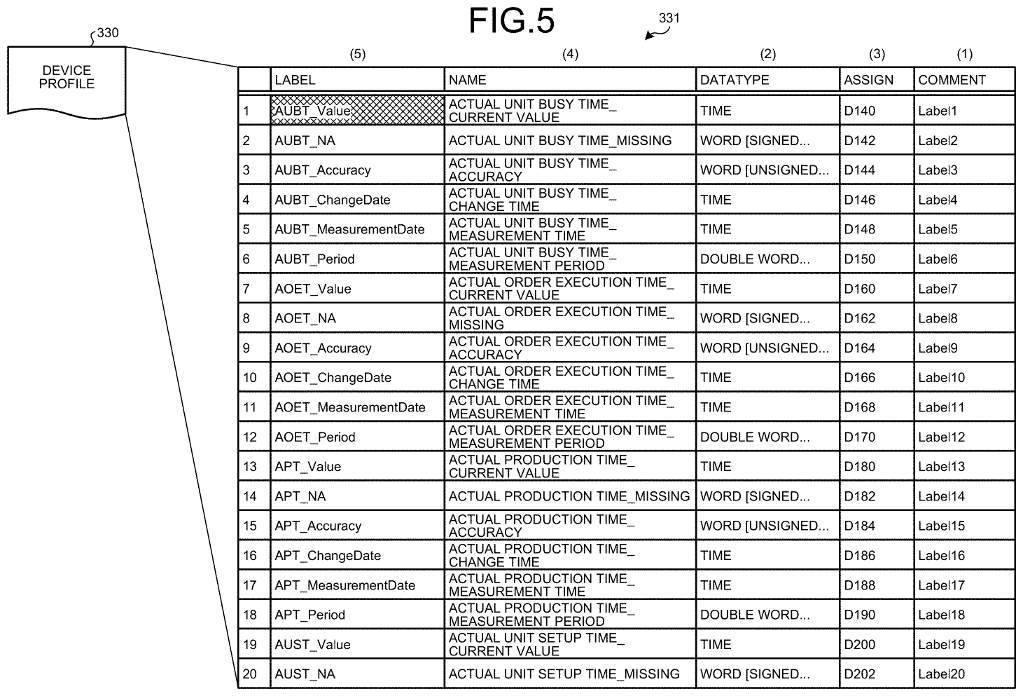

FIG. 5 is a diagram illustrating an example of a configuration of the device profile according to the first embodiment. FIG. 5 illustrates an example of device-monitoring item information 331 of the device profile 330. The device-monitoring item information 331 of the device profile 330 is a file in which the monitoring information is described at the head of each description content corresponding to each record of the project data 320. Each description content corresponding to each record of the project data 320 is illustrated as each row in FIG. 5. The device profile 330 is described according to a common format that is not dependent on the device. A file format of the device profile 330 is a file in a format such as text, Comma-Separated Values (CSV), or eXtensible Markup Language (XML), but is not necessarily limited by these formats. The monitoring information may be further described somewhere else in each description content of the device profile 330 besides the head thereof.

When a user instructs “generation of a device profile” via the input unit 20 on the design support device 1, the project analysis unit 41 and the device profile generation unit 42 execute the work described above and generate the device profile 330 by mapping the information in the fields corresponding to the “label name”, “data type”, “assignment (device/label)”, “remarks”, and “device profile information field” for each record of the project data 320, onto each row in FIG. 5 of the device-monitoring item information 331 of the device profile 330. As illustrated in FIG. 5, each description content corresponding to each record of the project data 320 of the device-monitoring item information 331 has fields of “LABEL”, “NAME”, “DATATYPE”, “ASSIGN”, and “COMMENT”.

Then, the information in the field corresponding to the “device profile information field” of the project data 320 is mapped onto the field of the “LABEL” of the description content of the device-monitoring item information 331. As a result, the monitoring information is stored in the field of the “LABEL” that is at the head of the description content of the device-monitoring item information 331. Moreover, the information in the field corresponding to the “data type” of the project data 320 is mapped onto the field of the “DATATYPE” of the description content of the device-monitoring item information 331. Similarly, the information sets in the fields corresponding to the “label name”, “assignment (device/label)”, and “remarks” are mapped onto the fields of the “COMMENT”, “ASSIGN”, and “NAME” of the description content of the device-monitoring item information 331, respectively. That is, the pieces of information of (1) to (5) for each row of FIG. 4 are mapped onto the corresponding fields of (1) to (5) for each row of FIG. 5, respectively, in such a manner that the same numbers correspond to each other. Therefore, the device profile 330 is a file in which the monitoring information is described at the head of each description content and additionally the device memory information that is the device information corresponding to the monitoring information is described.

Also, in the first embodiment, in a case where a calculation formula is defined in the specification data 310b, the device profile generation unit 42 generates operation information in which a calculation formula obtained by replacing an element or elements of the calculation formula defined in the specification data 310b with the monitoring item or items of the project data 320 is caused to be associated with a label attached to a result of operation of the calculation formula, and generates the device profile 330 including the device-monitoring item information 331 and the operation information. The calculation formula obtained by replacing the element(s) of the calculation formula defined in the specification data 310b with the monitoring item(s) of the project data 320 corresponds to a second calculation formula.

Specifically, the device profile generation unit 42 causes the display unit 50 to display a calculation formula setting screen at the time of generating the device profile 330. When causing the calculation formula setting screen to be displayed, the device profile generation unit 42 determines whether the monitoring items corresponding to the elements forming the calculation formula of the specification data 310b are included in the project data 320, and in a case where the monitoring items forming the calculation formula of the specification data 310b are included in the project data 320, the device profile generation unit 42 acquires the corresponding calculation formula from the specification data 310b and causes the calculation formula to be displayed on the calculation formula setting screen.

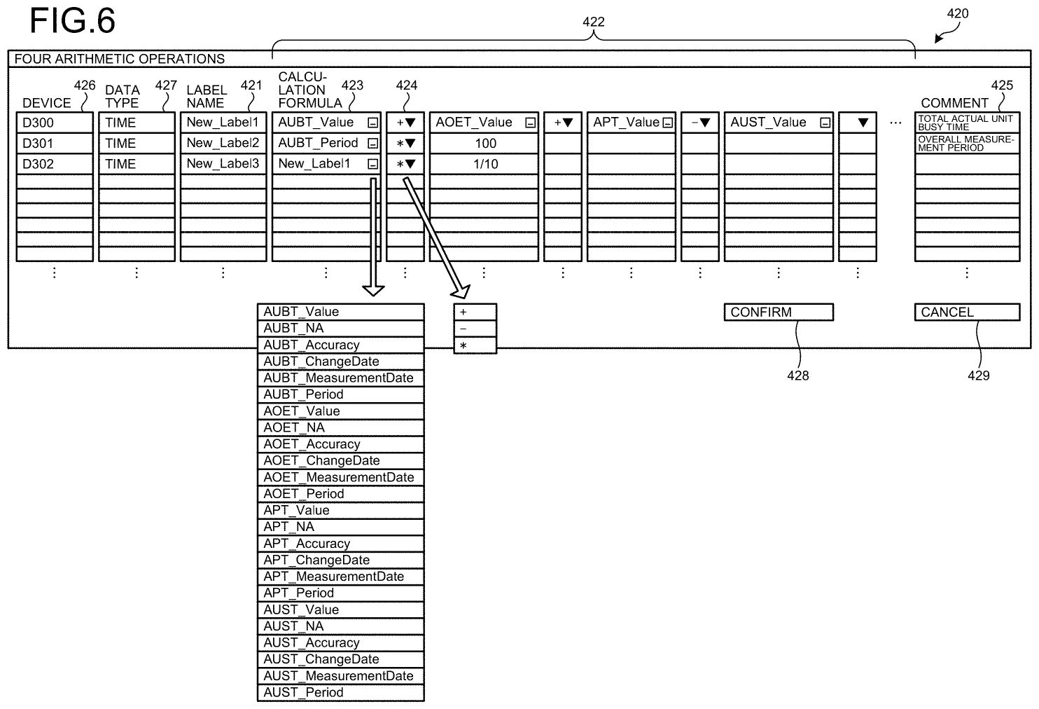

FIG. 6 is a diagram illustrating an example of the calculation formula setting screen according to the first embodiment. A calculation formula setting screen 420 includes a label name setting field 421, a calculation formula display area 422, a comment setting field 425, a device setting field 426, and a data type setting field 427.

The label name setting field 421 is a field used for setting an arbitrary name with respect to a result of the operation based on the calculation formula defined in the specification data 310. In one example, when the calculation formula setting screen 420 is displayed, the device profile generation unit 42 may set a default value in the label name setting field 421. The label name setting field 421 can be changed via the input unit 20 by a user.

In the calculation formula display area 422, a calculation formula corresponding to the label name is displayed. In one example, in the calculation formula display area 422, a calculation formula formed using the monitoring item and the operator acquired from the specification data 310 is displayed. The operator includes an operator indicating addition, subtraction, multiplication, division, or the like. As a result of this, one or more monitoring items can be subjected to four arithmetic operations to be one monitoring item of the device profile 330. That is, a result of the operation based on the calculation formula results in a new monitoring item and is hereinafter referred to as an operated monitoring item.

In the comment setting field 425, a comment the user wants to input is freely described. In one example, contents inputted by the user via the input unit 20 are set in the comment setting field 425.

In the device setting field 426, a device name of the device memory information for storing the result of the operation based on the calculation formula is set. In one example, a value inputted by a user via the input unit 20 is set in the device setting field 426. The device setting field 426 corresponds to a storage area setting field.

In the data type setting field 427, a data type of the device name set in the device setting field 426 is set. In one example, a value inputted by a user via the input unit 20 is set in the data type setting field 427.

Moreover, this configuration may be adapted to be able to input arbitrary label name, calculation formula, comment, and device so that a user can generate an arbitrary calculation formula in addition to the calculation formula formed using the monitoring item included in the project data 320 extracted by the device profile generation unit 42. That is, blanks are provided in the label name setting field 421, the calculation formula display area 422, the comment setting field 425, the device setting field 426, and the data type setting field 427 such that an arbitrary calculation formula can be inputted. The calculation formula display area 422 includes a monitoring item setting field 423 and an operator setting field 424. The monitoring item setting field 423 has a combo box configuration that allows for direct input and selection input from a list. The direct input is used when a numerical value is entered, for example. In the selection input, the monitoring items stored in the “device profile information field” defined in the project data 320 or stored under the field name “LABEL” of the device-monitoring item information 331 are displayed in a list form. A user can select her or his desired monitoring item from the list. The operator setting field 424 has a list box configuration that allows for selection of the operators of the four arithmetic operations or the like.

The calculation formula setting screen 420 further includes a “confirm” button 428 for confirming the edited contents when the editing on the calculation formula setting screen 420 is completed, and a “cancel” button 429 for canceling them. When the “confirm” button 428 is pressed down, the device profile generation unit 42 reflects the contents set on the calculation formula setting screen 420 in the device profile 330. That is, the device profile generation unit 42 generates, as a part of the device profile 330, the operation information including the operated monitoring item defined by the calculation formula including one or more monitoring items and one or more operators. Otherwise, when the “cancel” button 429 is pressed down, the device profile generation unit 42 does not reflect the contents set on the calculation formula setting screen 420 in the device profile 330.

Note that there is no limitation on a method of starting the calculation formula setting screen 420. In one example, a call button for the calculation formula setting screen 420 may be provided on an edit screen of the project data 320 so that a user can use the button to start the calculation formula setting screen 420. The calculation formula setting screen 420 may also be started by a user executing a shortcut menu, a command prepared in the design support device 1, or the like.

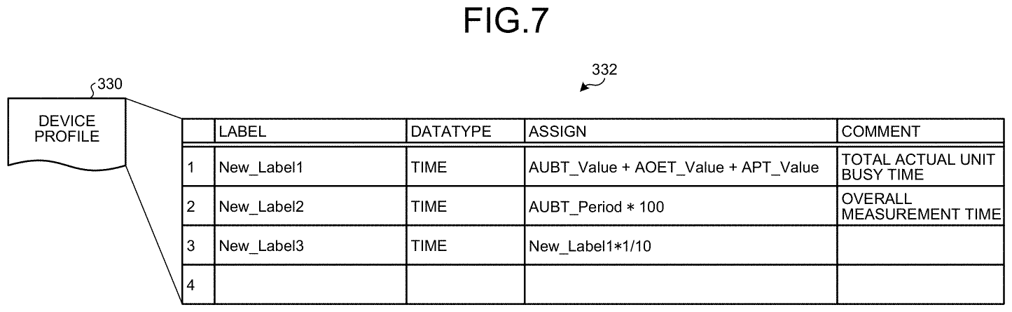

FIG. 7 is a diagram illustrating an example of a configuration of the device profile including the operated monitoring item based on the calculation formula according to the first embodiment. FIG. 7 illustrates an example of operation information 332 of the device profile 330. The operation information 332 of the device profile 330 is obtained by arranging the contents inputted on the calculation formula setting screen 420 in a predetermined format. In the example of FIG. 7, each record of the operation information 332 in a list form corresponds to each row of FIG. 7. One record is composed of a plurality of fields. The name of the field is a field name. In the operation information 332, fields corresponding to the field names of “LABEL”, “DATATYPE”, “ASSIGN”, and “COMMENT” are provided in each record. In the field with the field name of “LABEL”, the content set in the label name setting field 421 of the calculation formula setting screen 420 is inputted. In the field with the field name of “DATATYPE”, the content set in the data type setting field 427 of the calculation formula setting screen 420 is inputted. In the field with the field name of “ASSIGN”, the content set in the calculation formula display area 422 of the calculation formula setting screen 420 is inputted. In the field with the field name of “COMMENT”, the content set in the comment setting field 425 of the calculation formula setting screen 420 is inputted.

Note that the device-monitoring item information 331 illustrated in FIG. 5 and the operation information 332 illustrated in FIG. 7 are stored in one file of the device profile 300. A manner of storing each of the device-monitoring item information 331 and the operation information 332 in the file can be arbitrarily set.

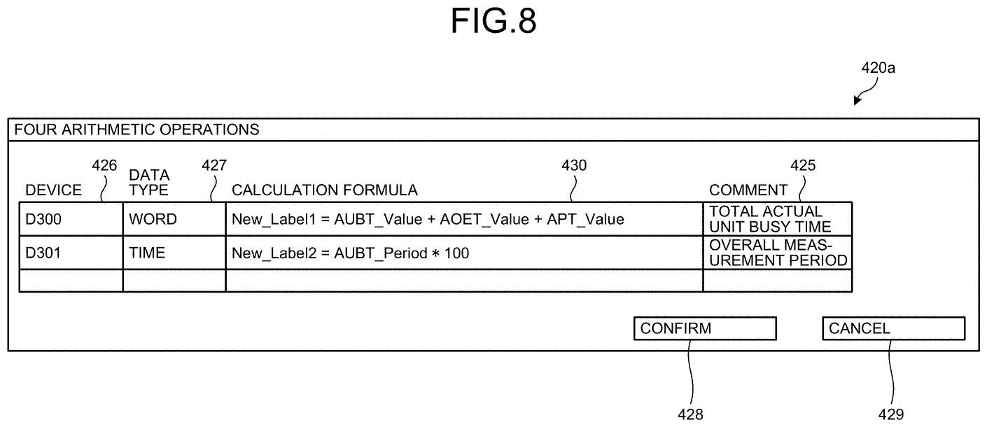

The calculation formula setting screen 420 of FIG. 6 has the format that allows for an input of the monitoring item or numerical value to the monitoring item setting field 423 of the calculation formula display area 422 and an input of the operator of the four arithmetic operations to the operator setting field 424, but may have another format. FIG. 8 is a diagram illustrating another example of the calculation formula setting screen according to the first embodiment. A calculation formula setting screen 420a of FIG. 8 includes a calculation formula setting field 430 that integrates the label name setting field 421, the monitoring item setting field 423, and the operator setting field 424 of FIG. 6. A relationship between the label name and the calculation formula can be inputted to the calculation formula setting field 430 in a free format. Note that the same components as those in FIG. 6 are denoted by the same reference numerals as those in FIG. 6, and the description thereof is omitted.

Returning to FIG. 1, the device profile storage unit 33 stores the device profile 330 generated by the device profile generation unit 42. In the first embodiment, the device profile 330 is a file including the device-monitoring item information 331 and the operation information 332 conforming to the common format that is not dependent on the devices 101 and 102.

The display unit 50 displays information necessary for generating the device profile 330. In one example, the display unit 50 displays the project data 320, the specification data 310, the device profile 330, the calculation formula setting screen 420, or the like.

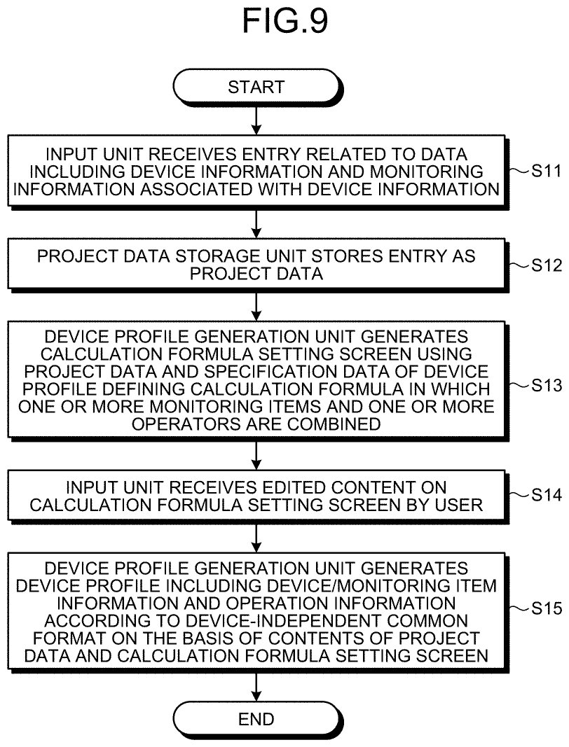

Next, a design support method to be executed by the design support device 1 according to the first embodiment will be described. FIG. 9 is a flowchart illustrating an example of a procedure of the design support method according to the first embodiment. First, the input unit 20 receives input details related to data including the device information and the monitoring information linked to the device information (step S11). The project data storage unit 32 stores the input details as the project data 320 (step S12).

Next, the device profile generation unit 42 generates the calculation formula setting screen 420 or 420a with use of the project data 320 and the specification data 310b of the device profile 330 in which the calculation formula based on a combination of one or more monitoring items and one or more operators is defined (step S13). In a case where all the monitoring items corresponding to the elements included in the calculation formula of the specification data 310b are included in the project data 320, the device profile generation unit 42 acquires the corresponding calculation formula from the specification data 310b and displays the acquired calculation formula on the calculation formula setting screen 420 or 420a. In a case where some of the monitoring items corresponding to the elements included in the calculation formula of the specification data 310b is/are not included in the project data 320, the device profile generation unit 42 does not display the corresponding calculation formula on the calculation formula setting screen 420 or 420a. In this way, the type of the calculation formula generated from the specification data 310b varies depending on the contents of the project data 320. In a case where the project data 320 includes the monitoring items of all the calculation formulas of the specification data 310b, all types of calculation formulas of the specification data 310b are generated. However, in a case where the project data 320 does not include some of the monitoring items of the calculation formulas of the specification data 310b, the calculation formula with the monitoring item not included in the project data 320 among the calculation formulas of the specification data 310b is not generated. On the calculation formula setting screen 420 or 420a, there are displayed a label name attached to the result of operation of the calculation formula and a device indicating a position in which the result of the calculation formula is stored.

Next, the input unit 20 receives edited contents of the calculation formula setting screen 420 or 420a from a user (step S14). After that, when the edited contents of the calculation formula setting screen 420 or 420a is confirmed, the device profile generation unit 42 generates the device profile 330 including the device-monitoring item information 331 and the operation information 332 according to a common format that is not dependent on the device, on the basis of the project data 320 and the contents of the calculation formula setting screen 420 or 420a (step S15). In the device/monitoring item information 331 of the device profile 330, it is specified that one monitoring item is monitored. On the other hand, in the operation information 332 of the device profile 330, it is specified that the operated monitoring item based on the calculation formula is monitored, the calculation formula being obtained by a combination of data acquired from one or more monitoring targets and the operator. The foregoing process completes the generation of the device profile 330.

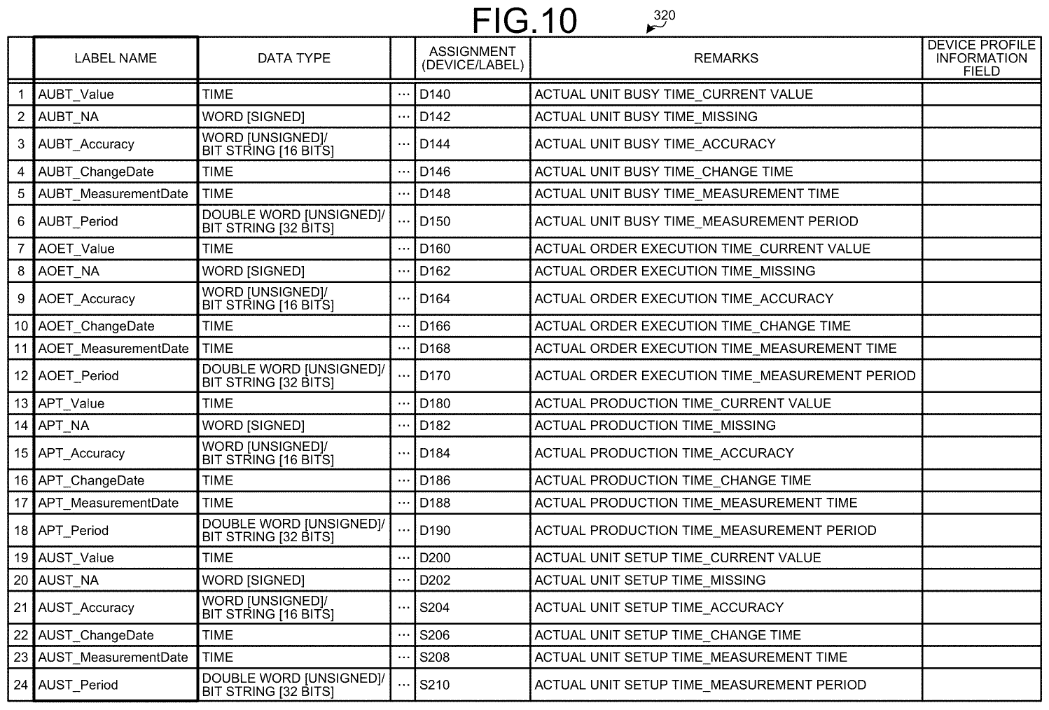

FIG. 10 is a table illustrating another example of the project data according to the first embodiment. In the project data 320 of FIG. 10, the monitoring information such as “AUBT_Value” is stored in a field corresponding to the “label name” in which identifier information is stored. That is, a user stores the monitoring information that she or he wants to include in the device profile 330, as the identifier information, in the project data 320. In this case, the identifier information is the monitoring information. As a result, the device information and the monitoring information are linked to each other in a record including the identifier information. A method by which the user stores the monitoring information as the identifier information is similar to the aforementioned method by which the user stores the monitoring information in the link information storage area. In the project data 320, nothing is stored in a field corresponding to the “device profile information field”. In addition, the project data 320 need not include the field corresponding to the “device profile information field”.

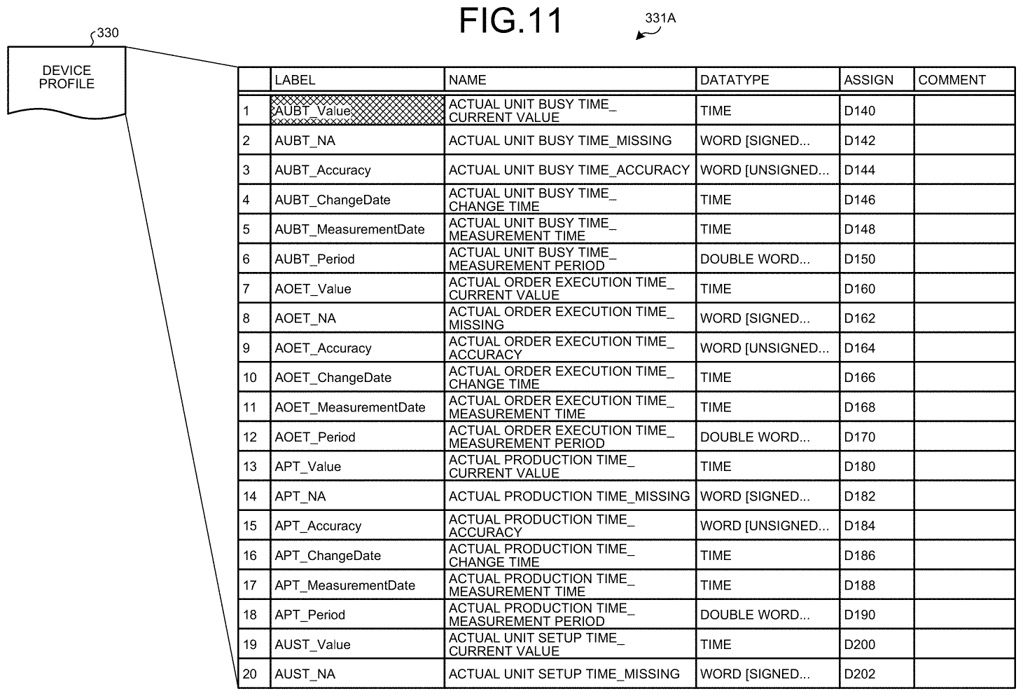

FIG. 11 is a diagram illustrating another example of the device profile according to the first embodiment. FIG. 11 illustrates an example of device-monitoring item information 331A of the device profile 330. In the device-monitoring item information 331A of the device profile 330 in FIG. 11, as with the device-monitoring item information 331 in FIG. 5, each description content corresponding to each record of the project data 320 includes fields of “LABEL”, “NAME”, “DATATYPE”, “ASSIGN”, and “COMMENT”. However, the field of “COMMENT” in the device-monitoring item information 331A is blank.

In this case, the project analysis unit 41 extracts, from the project data 320, information in the fields corresponding to the “label name”, “data type”, “assignment (device/label)”, and “remarks” to be used for creating the device-monitoring item information 331A of the device profile 330. The device profile generation unit 42 generates the device profile 330 by mapping these extracted information pieces outputted from the project analysis unit 41 according to the format of the device-monitoring item information 331A of the device profile 330.

Then, the information in the field corresponding to the “label name” of the project data 320 is mapped onto the field of “LABEL” of the description content of the device-monitoring item information 331A. As a result, the monitoring information is stored in the field of “LABEL” that is at the head of the description content of the device-monitoring item information 331A. Moreover, the information in the field corresponding to “data type” of the project data 320 is mapped onto the field of “DATATYPE” of the description content of the device-monitoring item information 331A. Similarly, the information in the fields corresponding to the “assignment (device/label)” and “remarks” is mapped onto the fields of “ASSIGN” and “NAME” of the description content of the device-monitoring item information 331A, respectively. As a result, the device profile 330 is a file in which the monitoring information is described at the head of each description content, and also the device memory information corresponding to that monitoring information is described.

Note that as illustrated in FIG. 1, the design support device 1 is configured with a computer including a CPU 40 that executes various kinds of processings, a memory 30 that stores information, the input unit 20 that inputs information according to an operation of a user, the communication unit 10 that is a connection interface with a device external to the design support device 1, and the display unit 50 that displays information. The CPU 40, the memory 30, the input unit 20, the communication unit 10, and the display unit 50 are connected by a bus line 60.

The memory 30 includes a random access memory (RAM), a read only memory (ROM), or an external storage device. A design support program in which a procedure of generating the device profile 330 to be executed by the CPU 40 is described is loaded into the RAM, and also data used by the CPU 40 is temporarily held in the RAM. In the ROM, there is stored Basic Input/Output System (BIOS) or Unified Extensible Firmware Interface (UEFI) that is a program for basic control of a computer that is the design support device 1. The external storage device is a hard disk drive (HDD) or a solid state drive (SSD). In the external storage device, the design support program and various types of data are stored. Note that the design support program may be stored in the ROM.

The programs stored in the ROM and the external storage device are loaded into the RAM. The CPU 40 executes various kinds of processings by loading the design support program into the RAM. In the first embodiment, the CPU 40 executes the design support program to thereby implement functions of the processing units of the project analysis unit 41 and the device profile generation unit 42 described above.

The design support program may be a type to be stored in a storage medium that can be read by a computer. The design support device 1 may store the design support program stored in the storage medium in an external storage device. The storage medium may be a portable storage medium being a flexible disk, or may be a flash memory being a semiconductor memory. The design support program may be installed on a computer to be the design support device 1 from another computer or server device via the network 150.

In the first embodiment, the device profile 330 can be automatically generated from the project data 320, so that man hours and errors in creating the device profile 330 by a user can be reduced. Moreover, by using the label linked to the monitoring item defined in the device profile 330, a user can create a program for collecting data of a plurality of types of devices and displaying the collected data without relying on the vendor.

Also, conventionally, in a case of monitoring an operated monitoring item based on a calculation formula of a combination of one or more monitoring items and one or more operators, it has been necessary to incorporate the calculation formula in which the monitoring items and the operators are combined, into the program. Therefore, when the device connected to the device is changed, it has been necessary to change the device profile 330 and also the program has to be changed in association with the device profile 330.

On the other hand, in the first embodiment, the calculation formula setting screens 420 and 420a are displayed on the display unit 50 on the basis of the calculation formula in the specification data 310b. On the calculation formula setting screens 420 and 420a, a user makes an association among the calculation formula including one or more monitoring items and one or more operators, the label attached to the result of operation of the calculation formula, and the device as the storage area in which the result of operation is stored. According to the finally-obtained result, the operation information 332 of the device profile 330 is generated. That is, in the operation information 332, the result of operation of the calculation formula including one or more monitoring items and one or more operators is associated with one label. Then, the program for acquiring and displaying data from the device so as to read the label can be created, so that the program does not need to be changed even if the calculation formula is subjected to change. For example, when the configuration of the monitoring target in the FA system 100 is changed, the device profile generation unit 42 changes the calculation formula associated with the label of the operation information 332 on the basis of the project data 320 that has been changed. As a result, the program created in the form that refers to the label can monitor the FA system 100 without changing the contents of the program.

### Second Embodiment

In the first embodiment, an example has been described for the case of supporting generation of the parts related to the device-monitoring item information and the operation information in the device profile. In a second embodiment, description is given for a design support device, a design support method, and a design support program that support generation of protocol information that is information specifying a method of acquiring a monitoring item defined by device-monitoring item information in a device profile.

A configuration of the design support device 1 according to the second embodiment is similar to that of the first embodiment, and a function of the device profile generation unit 42 of the CPU 40 is different from that of the first embodiment. Hereinafter, differences from the first embodiment will only be described.

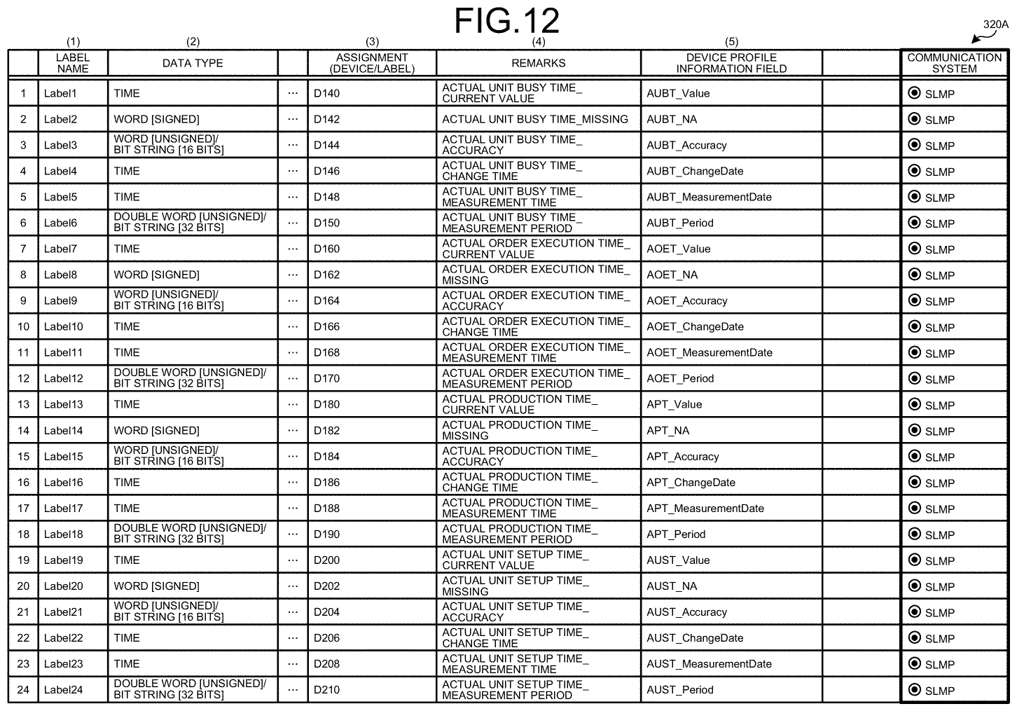

FIG. 12 is a table illustrating an example of a configuration of project data according to the second embodiment. Project data 320A of the second embodiment is obtained by adding a field name “communication system” to the project data 320 of FIG. 4. In a field of “communication system”, a method of acquiring information of subdevices constituting the device is described. More specifically, the “communication system” refers to a communication protocol for acquiring data of a monitoring item in the device-monitoring item information 331. As the method of acquiring the information of the subdevice, Seamless Message Protocol (SLMP) communication, an SQL statement, or the like is described. FIG. 12 illustrates a case where “SLMP” is designated as the “communication system”.

The device profile generation unit 42 generates the device profile 330 including the protocol information that is information specifying the method of acquiring data of the monitoring item in the device-monitoring item information 331 by “communication system” being set, in addition to the device-monitoring item information 331 that is information in which the device information and the monitoring information described in the first embodiment are linked. Note that since the device-monitoring item information 331 is illustrated in FIG. 5 of the first embodiment, the description thereof will be omitted here. The device profile generation unit 42 generates the device profile 330 including the protocol information from the “label name”, the “assignment (device/label)”, and the “communication system” of the project data 320A.

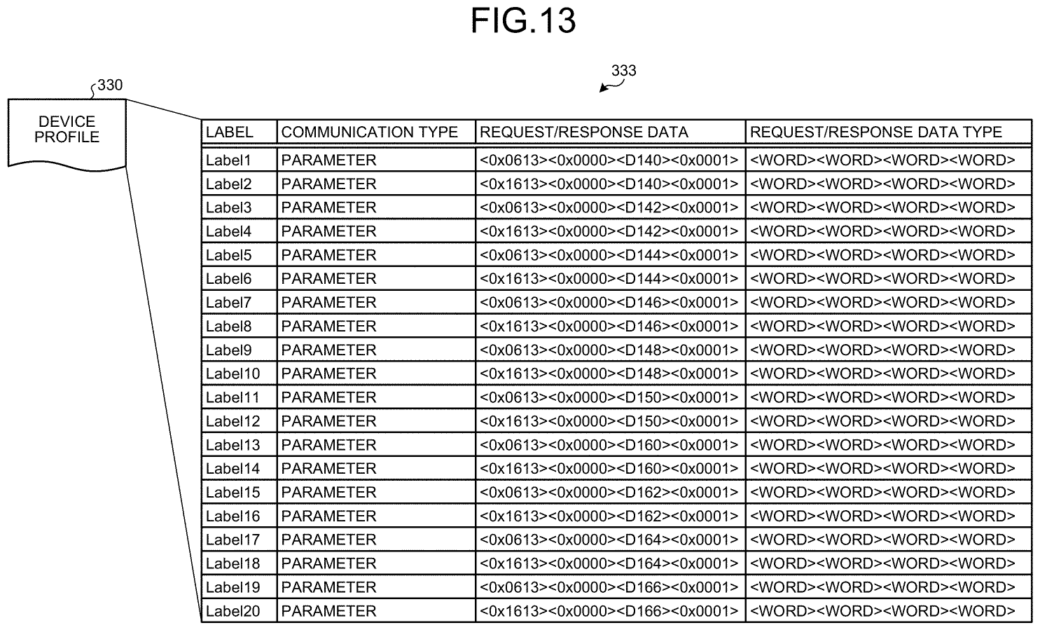

FIG. 13 is a diagram illustrating an example of a configuration of the device profile according to the second embodiment. FIG. 13 illustrates protocol information 333 of the device profile 330. The protocol information 333 includes “LABEL”, “COMMUNICATION TYPE”, “REQUEST/RESPONSE DATA”, and “REQUEST/RESPONSE DATA TYPE” as field names. Note that, here, a case where “SLMP” is designated as a “communication system” of the project data 320A will be exemplified.

In “LABEL”, processing that acquires data of the monitoring item is identified. In “COMMUNICATION TYPE”, a communication type is indicated. In a case where the “communication system” is SLMP, as communication type, there are “PARAMETER” indicating that a parameter of a device is read, “COMMAND” indicating that a command is issued, and the like.

The “REQUEST/RESPONSE DATA” refers to an instruction corresponding to the communication system for acquiring data of the monitoring item indicated in the “LABEL”. The acquisition of data of the monitoring item includes reading data from a device and writing data into a device. In a case where the “communication system” is SLMP, the instruction is described in “<command><subcommand><data><data size>”. The content of the instruction is specified by “<command><subcommand>”. It is a read command when “<command>” is “<0x0613>”, or it is a write command when “<command>” is “<0x1613>”. In “<data>”, a device indicating a storage area subject to read or write is described. In “<data size>”, the size of the device designated by “<data>” is described. In this example, the size of the device indicated by “<data>” is set in such a manner that data of one monitoring item is acquired by one instruction. In an example of a first row of the protocol information 333, there are described contents that a value stored in a device “D140” is read, with use of a data read command “<0x0613><0x0000>”. On the other hand, in an example of a second row of the protocol information 333, there are described contents that data is written in a device “D140”, with use of a data write command “<0x1613><0x0000>”.

In “REQUEST/RESPONSE DATA TYPE”, a data type of the instruction described in “REQUEST/RESPONSE DATA” is described. The example of the first row of the protocol information 333 indicates that all of “<command>”, “<subcommand>”, “<data>”, and “<data size>” are of a word type.

The device profile generation unit 42 stores the device profile 330 including the protocol information 333 generated on the basis of the project data 320A, in the device profile storage unit 33.

As described above, in the case of creating the program for acquiring the data according to the device profile 330 in which the processing related to the acquisition of the monitoring item is defined by the label, it is only necessary to describe the label associated with the processing for the data acquisition, in the program.

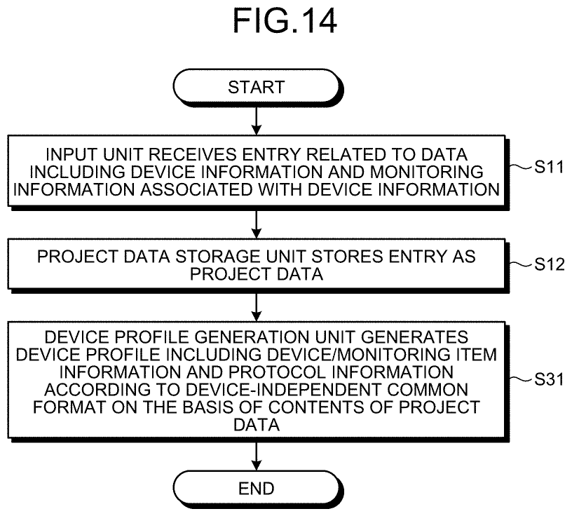

Next, the design support method to be executed by the design support device 1 according to the second embodiment will be described. FIG. 14 is a flowchart illustrating an example of a procedure of the design support method according to the second embodiment. Note that hereinafter, differences from the first embodiment will be described.

In the second embodiment, after step S12, the device profile generation unit 42 generates the device profile 330 including the device-monitoring item information 331 and the protocol information 333 according to a common format that is not dependent on the device, on the basis of the content of the project data 320A (step S31). The protocol information 333 uses a command used in the communication protocol specified in the “communication system” of the project data 320A to create an instruction for acquiring the value of the device specified in the “assignment (device/label)” of the project data 320A. Then, “REQUEST/RESPONSE DATA” is generated by attaching a “label name” to the instruction created. This process is performed for all records of the project data 320A. The processing is thus completed. Note that in the second embodiment as well, a design support program in which the procedure of the design support method is described can be executed by a computer. The design support program may be stored in a storage medium that can be read by a computer, or may be installed on a computer to be the design support device 1 from another computer or a server device via the network 150.

In the second embodiment, the device profile generation unit 42 generates the device profile 330 including the protocol information 333 that specifies the processing details for acquiring the monitoring items included in the device-monitoring item information 331 and 331A generated from the project data 320A. The protocol information 333 includes the instruction for acquiring the value of the device specified in the “assignment (device/label)” using the command of the communication protocol specified in the “communication system” of the project data 320A. By virtue of this, a user only needs to designate a label associated with a processing related to data desired to be collected in the program for collecting data. That is, there is no need to create a communication command for acquiring the monitoring item included in the device-monitoring item information 331 and 331A of the device profile 330 in the program, thereby making it possible to reduce the user's time and effort in creating the program and reduce errors in creating the program.

### Third Embodiment

In the protocol information of the device profile of the second embodiment, the instruction to acquire the monitoring items in the device-monitoring item information one by one is created. In a third embodiment, description is given for a design support device, a design support method, and a design support program that generate a device profile including protocol information specifying processing details for acquiring a plurality of monitoring items in the device-monitoring item information at a time.

A configuration of the design support device 1 according to the third embodiment is similar to that of the first and second embodiments. Hereinafter, differences from the first and second embodiments will only be described.

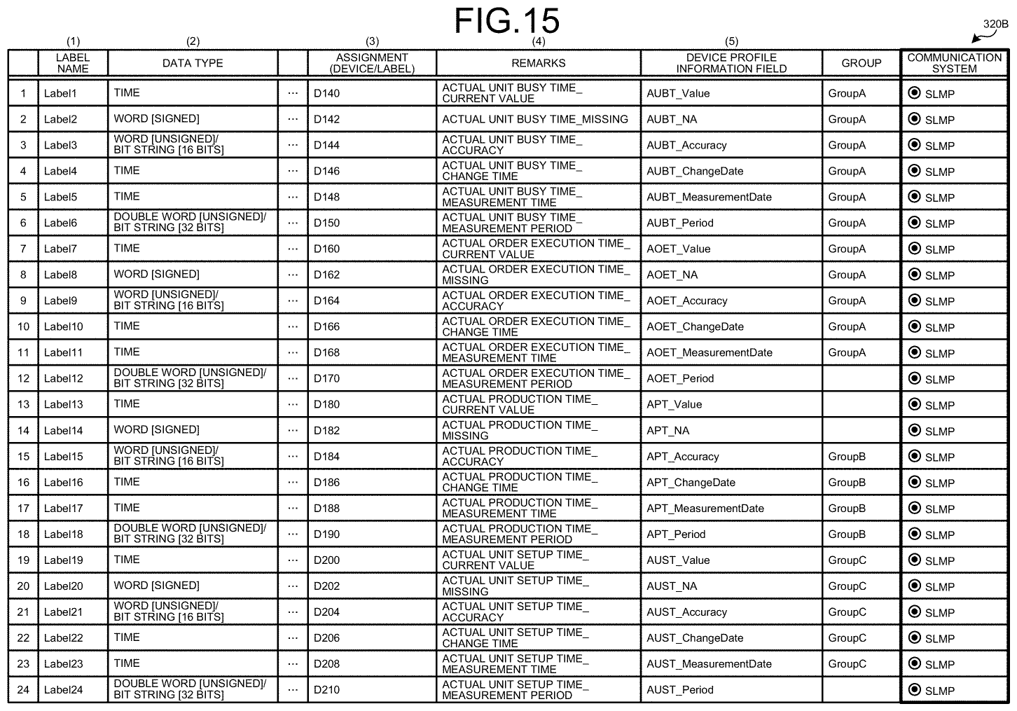

FIG. 15 is a table illustrating an example of a configuration of project data according to the third embodiment. Project data 320B of the third embodiment is obtained by adding a field name “group” to the project data 320A of FIG. 12. In a field of “group”, a group that is a range for acquiring a plurality of monitoring items by one communication command is designated. That is, the “group” is information for grouping the monitoring items and specifying which group each record belongs to. Note that for “group”, an area where devices are arranged in succession without any free space is designated in an area of a shared memory. The designation of “group” may be made by a user via the input unit 20, or by the device profile generation unit 42 extracting a storage area in which data is successively stored in the area of the shared memory. In this example, three groups being “GroupA”, “GroupB”, and “GroupC” are designated in the fields of the “group”.

In a case where “group” is set in the project data 320B at the time of generating the protocol information, the device profile generation unit 42 detects a start address and a last address of devices for which the monitoring items of records grouped are retained. The device profile generation unit 42 also calculates a data size from the detected start address and last address. Then, the device profile generation unit 42 generates an instruction to acquire the monitoring items of the records grouped at a time, with use of the start address and the data size. In a case where the “communication system” is SLMP as described above, the instruction is described in the form of “<command><subcommand><data><data size>”. Therefore, the device corresponding to the start address of the grouped records is set in “<data>”, and a total size of the devices for which the monitoring items of the records grouped are stored is set in “<data size>”.

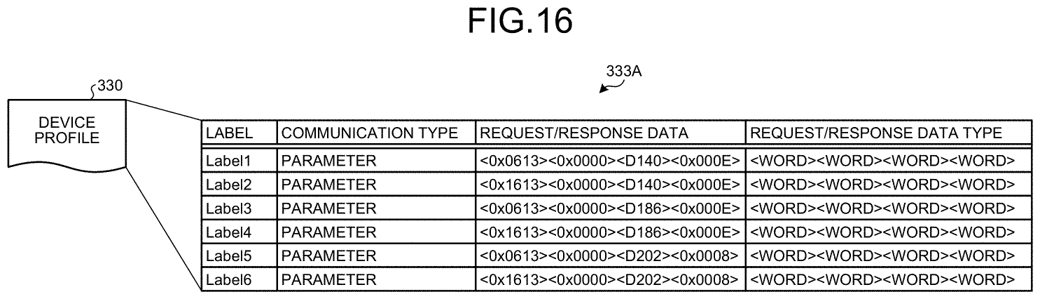

FIG. 16 is a diagram illustrating an example of a configuration of the device profile according to the third embodiment. FIG. 16 illustrates protocol information 333A of the device profile 330. A configuration of the protocol information 333A is similar to that of FIG. 13 of the second embodiment. However, “<data size>” described in the “REQUEST/RESPONSE DATA” is different from that in FIG. 13, in which the size of the shared memory storing the monitoring items of the records grouped is designated.

Note that a procedure of the design support method according to the third embodiment is similar to that of the second embodiment, and so its description is omitted. In the third embodiment as well, a design support program in which the procedure of the design support method is described can be executed by a computer. The design support program may be stored in a storage medium that can be read by a computer, or may be installed on a computer to be the design support device 1 from another computer or a server device via the network 150.

In the third embodiment, a device profile 330 is generated, the profile 330 including the protocol information 333A for grouping data of the monitoring items stored in the successive areas in the shared memory and acquiring the data of the monitoring items group by group. This can reduce the communication traffic and allow for efficient data acquisition as compared to the case where data is acquired using the instruction to acquire the data of the monitoring items in the device-monitoring item information 331 and 331A of the device profile 330 one by one.

### Fourth Embodiment

In a fourth embodiment, description is given for a design support device, a design support method, and a design support program that can generate a device profile including the device-monitoring item information and the operation information of the first embodiment and the protocol information of the second and third embodiments.

A configuration of the design support device 1 according to the fourth embodiment is similar to that of the first, second, and third embodiments. Hereinafter, differences from the first, second, and third embodiments will only be described.

The device profile generation unit 42 generates the device profile 330 including the device-monitoring item information 331 or 331A and the operation information 332 described in the first embodiment and the protocol information 333 or 333A described in the second and third embodiments. The device-monitoring item information 331 or 331A and the operation information 332 are similar to those described in the first embodiment, but the protocol information is different from that of the second and third embodiments. In the fourth embodiment, when generating the protocol information 333 or 333A, the device profile generation unit 42 generates protocol information including an instruction to acquire the operated monitoring item of each record of the operation information 332, in addition to the instruction to acquire the monitoring item of each record of the device-monitoring item information 331 or 331A.

In the fourth embodiment, in a case where the specification data 310b has a definition of a calculation formula, the device profile generation unit 42 causes the calculation formula setting screen 420 to be displayed on the display unit 50 when generating the device profile 330. When causing the calculation formula setting screen 420 to be displayed, the device profile generation unit 42 determines whether the monitoring items forming the calculation formula of the specification data 310b are included in the project data 320 or 320A, and in a case where the monitoring items forming the calculation formula of the specification data 310b are included in the project data 320 or 320A, the device profile generation unit 42 acquires the corresponding calculation formula from the specification data 310b and causes the calculation formula to be displayed on the calculation formula setting screen 420. In addition, the device profile generation unit 42 causes the calculation formula setting screen 420 to display a field for setting the communication system when acquiring a result of operation of the calculation formula.

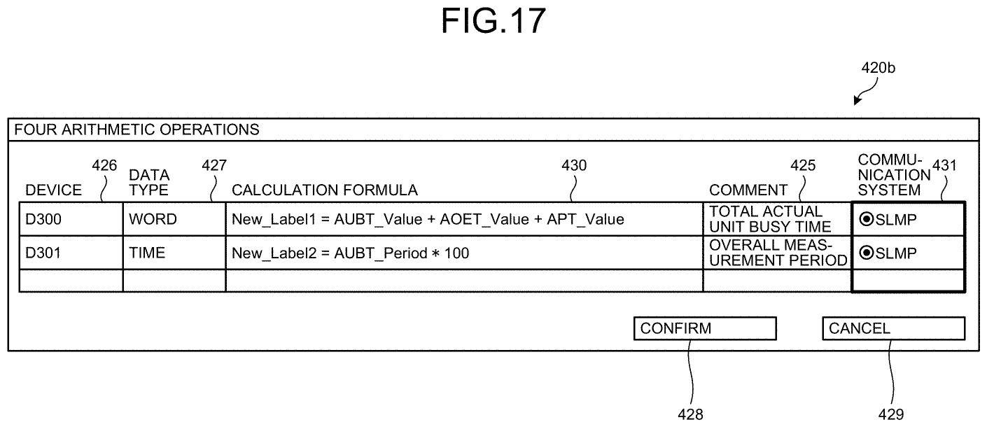

FIG. 17 is a diagram illustrating an example of the calculation formula setting screen according to the fourth embodiment. FIG. 17 illustrates a calculation formula setting screen 420b having a form including the calculation formula setting field 430 to which a relationship between a label name and a calculation formula can be inputted in a free format. Compared to FIG. 8 of the first embodiment, the calculation formula setting screen 420b further includes a communication system setting field 431. As with the second embodiment, the communication system setting field 431 is a field used to designate a method of acquiring information of a subdevice. Note that the rest of the configuration is similar to that of FIG. 8 and so its description is omitted. Also, a communication system setting field may be provided on the calculation formula setting screen 420 of FIG. 6 of the first embodiment.

When a user inputs setting contents on the calculation formula setting screen 420b and presses the “confirm” button 428 down, the device profile generation unit 42 reflects the contents set on the calculation formula setting screen 420b in the device profile 330. In this example, the device profile generation unit 42 generates the device profile 330 including the device-monitoring item information 331 illustrated in FIG. 5, the operation information 332 illustrated in FIG. 7, and the protocol information. The protocol information includes protocol information including an instruction to acquire data calculated by the operated monitoring item, in addition to the protocol information 333 or 333A illustrated in FIG. 13 or 16.

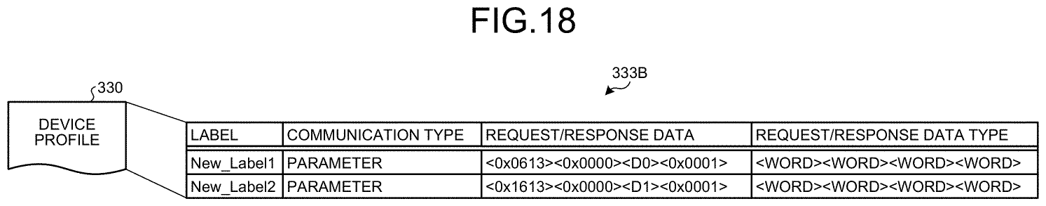

FIG. 18 is a diagram illustrating an example of the device profile according to the fourth embodiment. FIG. 18 illustrates protocol information 333B of the device profile 330. The protocol information 333B is basically similar to the protocol information 333 illustrated in FIG. 13 of the second embodiment. However, in the “REQUEST/RESPONSE DATA”, the set of “<data>” and “<data size>” are changed to contents for acquiring the data calculated by the operated monitoring item.

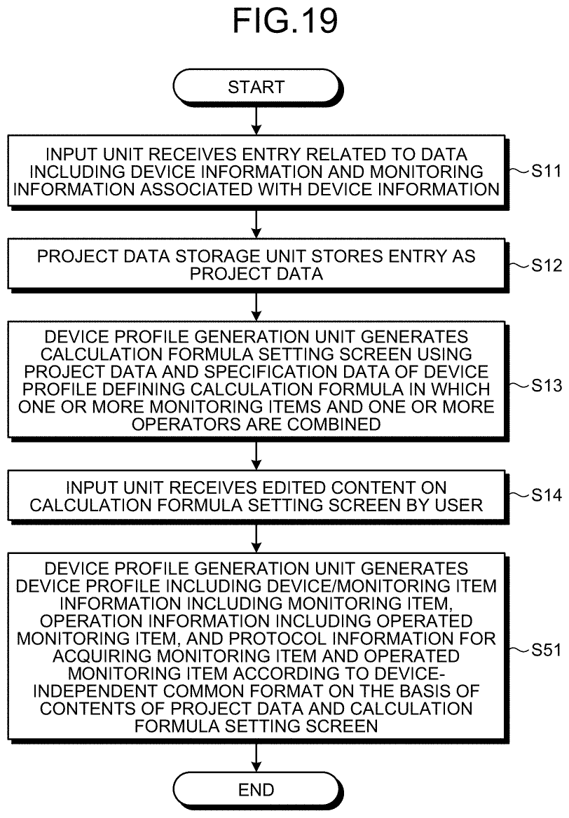

Next, the design support method to be executed by the design support device 1 according to the fourth embodiment will be described. FIG. 19 is a flowchart illustrating an example of a procedure of the design support method according to the fourth embodiment. Note that hereinafter, differences from FIG. 9 of the first embodiment will be mainly described. After step S14, on the basis of the contents of the project data 320, 320A, or 320B and the calculation formula setting screen 420, 420a, or 420b, the device profile generation unit 42 generates the device profile 330 including the device-monitoring item information 331 or 331A including the monitoring items, the operation information 332 including the operated monitoring items, and the protocol information 333, 333A, or 333B for acquiring the monitoring items and the operated monitoring items according to a common format that is not dependent on the device (step S51). The processing is thus completed. Note that in the fourth embodiment as well, a design support program in which the procedure of the design support method is described can be executed by a computer. The design support program may be stored in a storage medium that can be read by a computer, or may be installed on a computer to be the design support device 1 from another computer or a server device via the network 150.

In the fourth embodiment, the device profile generation unit 42 generates the device profile 330 including, in addition to the device-monitoring item information 331 or 331A, the operation information 332 that includes the operated monitoring item defined by the calculation formula including one or more monitoring items and one or more operators, and the protocol information 333, 333A, or 333B that includes the instruction to acquire the monitoring item in the device-monitoring item information 331 or 331A and the result of operation as the operated monitoring item in the operation information 332. By this means, a user only needs to designate a label associated with a processing related to data of the operated monitoring item she or he wants to collect, in the program for collecting data. That is, there is no need to create a communication command for acquiring the data of the operated monitoring item indicated by the operation information of the device profile 330 in the program, thereby making it possible to reduce the user's time and effort in creating the program.

### Fifth Embodiment

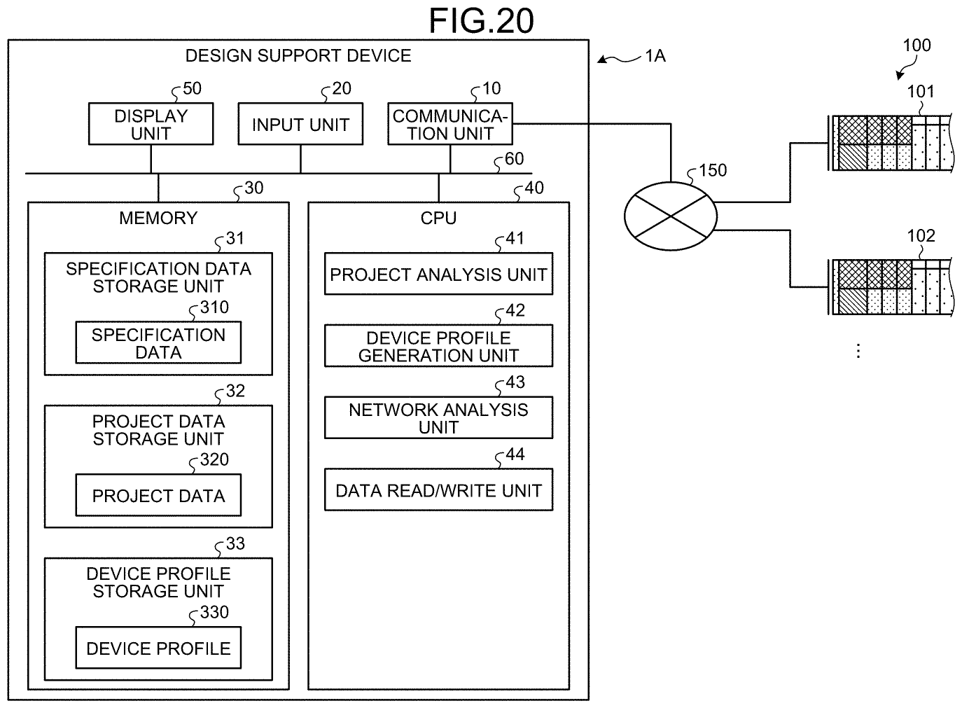

FIG. 20 is a block diagram schematically illustrating an example of a configuration of a design support device and an FA system according to a fifth embodiment. Note that hereinafter, parts that are different from those of the first to fourth embodiments will be mainly described, and parts that are identical to those of the first to fourth embodiments will not be described. A design support device 1A according to the fifth embodiment is different from the design support device of FIG. 1 in that the CPU 40 includes a network analysis unit 43 and a data read/write unit 44. In addition, the fifth embodiment is based on the assumption that the project data 320 is stored in the devices 101 and 102 of the FA system 100.

The network analysis unit 43 extracts route information to and from the subdevices constituting the devices 101 and 102 connected thereto via the network 150. As the route information, route information between the design support device 1A and the subdevices constituting each of the devices 101 and 102, set by a user via the input unit 20 may be extracted. The network analysis unit 43 passes the extracted route information to the data read/write unit 44.

The data read/write unit 44 uses the route information to acquire the project data 320, 320A, or 320B from the subdevice on the network 150. Specifically, the data read/write unit 44 communicates with the subdevice using the route information. As a result, the subdevice connected to the design support device 1A on the network 150 is detected. Then, the data read/write unit 44 acquires the project data 320, 320A, or 320B from each subdevice detected, and stores the project data in the project data storage unit 32.

The project analysis unit 41 analyzes the project data 320, 320A, or 320B acquired from each subdevice, and the device profile generation unit 42 generates the device profile 330 from the project data 320, 320A, or 320B by the method described in any of the first to fourth embodiments described above.

In the first to fourth embodiments, the design support device 1 generates the device profile 330 from the project data 320, 320A, or 320B generated offline. However, in the fifth embodiment, the design support device 1A generates the device profile 330 from the project data 320, 320A, or 320B acquired from the subdevice connected online.

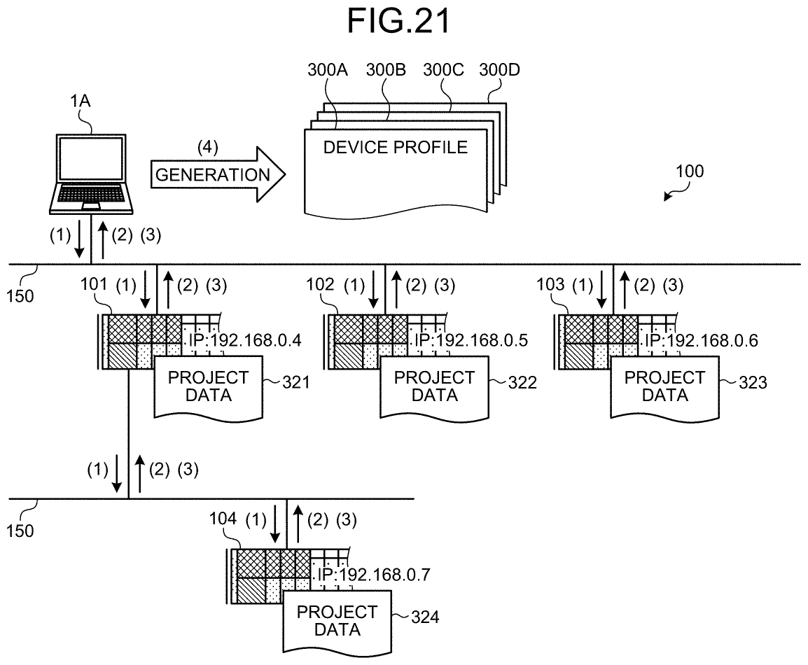

Next, a procedure in which the design support device 1A reads the project data 320, 320A, or 320B from the subdevice connected to the network 150 and generates the device profile 330 will be described. FIG. 21 is a diagram illustrating an example of the configuration of the design support device and the FA system according to the fifth embodiment. The FA system 100 includes devices 101, 102, 103, and 104. In one example, the device 101 is a laser processing machine, the device 102 is a rotary cutter, the device 103 is a conveyor, and the device 104 is a packaging machine. Each of the devices 101, 102, 103, and 104 includes a PLC and is controlled by the PLC. The PLC is one of the subdevices constituting each of the devices 101, 102, 103, and 104.

A user can write project data 321, 322, 323, and 324 in storage units equipped in the PLCs of the devices 101, 102, 103, and 104 via the data read/write unit 44 of the design support device 1A. The devices 101, 102, 103, and 104 hold the project data 321, 322, 323, and 324 in the storage units of their respective PLCs. The project data 321, 322, 323, and 324 is configured in a list form similar to the project data 320, 320A, and 320B described in the first to fourth embodiments.

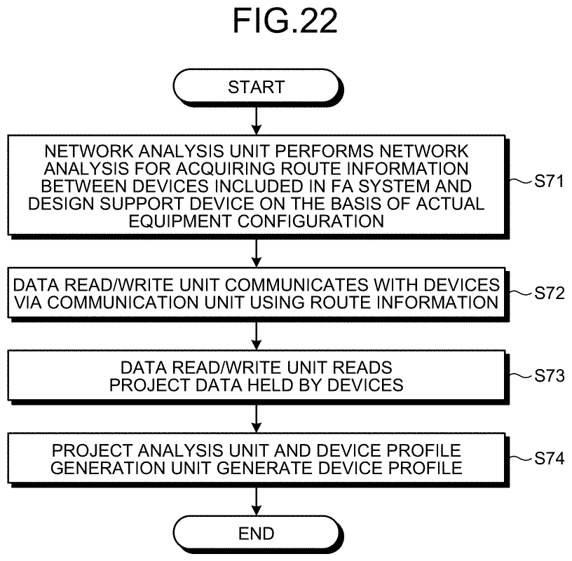

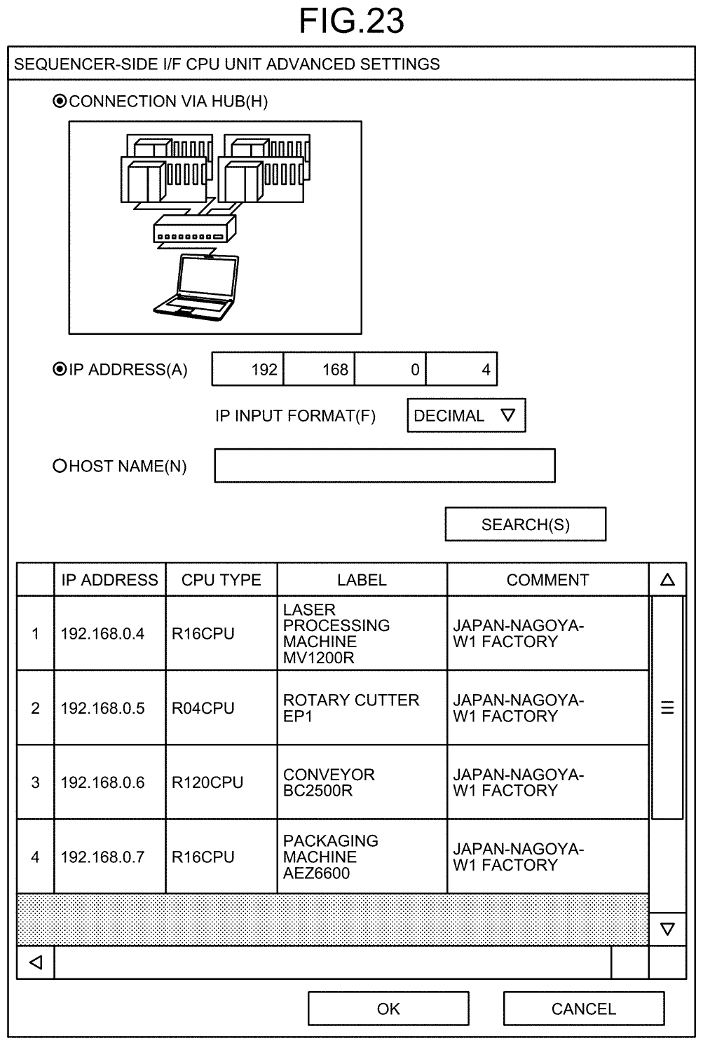

FIG. 22 is a flowchart illustrating an example of a procedure of a design support method according to the fifth embodiment. First, the network analysis unit 43 performs network analysis for acquiring route information, which is set by a user via the input unit 20, between the devices 101, 102, 103, and 104 which constitute the FA system 100 and the design support device 1A on the basis of an actual device configuration (step S71). The network analysis allows for acquisition of information such as IP addresses of the devices 101, 102, 103, and 104 or a model name of the subdevice on the same network 150 as the design support device 1A. FIG. 23 is a diagram illustrating an example of a screen of the display unit of the design support device according to the fifth embodiment. As illustrated in FIG. 23, on the display unit 50 of the design support device 1A that supports the generation of the device profile 330, there is displayed a result of the network analysis of the FA system 100.

Referring back to FIG. 22, the route information acquired by the network analysis unit 43 is sent to the data read/write unit 44, and the data read/write unit 44 communicates with the devices 101, 102, 103, and 104 via the communication unit 10 using the route information (step S72). In FIG. 21, (1) and (2) indicate signal flows of this communication.

Moreover, the data read/write unit 44 reads the project data 321, 322, 323, and 324 held by the devices 101, 102, 103, and 104 (step S73). At this time, the data read/write unit 44 functions as a project data reader, and (3) in FIG. 21 indicates a flow of the data to be read out. The data read/write unit 44 holds the project data 321, 322, 323, and 324 that has been read, in the project data storage unit 32.

After that, as described in the first to fourth embodiments, the project analysis unit 41 and the device profile generation unit 42 generate device profiles 300A, 300B, 300C, and 300D (step S74). In FIG. 21, (4) indicates the situation at this time. Here, the device profiles 300A, 300B, 300C, and 300D correspond to the project data 321, 322, 323, and 324, respectively. Note that in the fifth embodiment as well, a design support program in which the procedure of the design support method is described can be executed by a computer. The design support program may be stored in a storage medium that can be read by a computer, or may be installed on a computer to be the design support device 1A from another computer or a server device via the network 150.

As described above, the design support device 1A according to the fifth embodiment can automatically generate the device profiles 300A, 300B, 300C, and 300D by reading the project data 321, 322, 323, and 324 held by the devices 101, 102, 103, and 104 on the basis of the route information acquired by the network analysis unit 43. Note that the project data 321, 322, 323, and 324 may include the route information of the devices such as the IP addresses.

When a change is made in the project data 321, 322, 323, and 324 of the devices 101, 102, 103, and 104 in operation, the device profiles 300A, 300B, 300C, and 300D need to be corrected, but the design support device 1A according to the fifth embodiment can automatically generate the device profiles 300A, 300B, 300C, and 300D on the basis of the actual subdevice configuration. This can reduce the man hours for generating the device profiles 300A, 300B, 300C, and 300D and can also reduce errors in the device profiles 300A, 300B, 300C, and 300D.

The configurations illustrated in the above embodiments merely illustrate examples, and can each be combined with other publicly known techniques or can be combined together, and can each be partially omitted and/or modified without departing from the scope of the present disclosure.

### REFERENCE SIGNS LIST

1, 1A design support device; 10 communication unit; 20 input unit; 30 memory; 31 specification data storage unit; 32 project data storage unit; 33 device profile storage unit; 40 CPU; 41 project analysis unit; 42 device profile generation unit; 43 network analysis unit; 44 data read/write unit; 50 display unit; 60 bus line; 100 FA system; 101, 102, 103, 104 device; 150 network; 300, 300A, 300B, 300C, 300D device profile; 310, 310a, 310b specification data; 320, 320A, 320B, 321, 322, 323, 324 project data; 330 device profile; 331, 331A device/monitoring item information; 332 operation information; 333, 333A, 333B protocol information; 420, 420a, 420b calculation formula setting screen.

1. A design support device comprising:
a project memory to store project data including device information that is information about a device and monitoring information that is information about a monitoring item and is linked to the device information, the project data having information necessary to control the device, stored therein;
a specification memory to store, therein, specification data that is data in which a specification serving as a design guideline of a device profile is defined, and includes an operated monitoring item name defined by a first calculation formula; and
device profile generation circuitry to generate a device profile including device-monitoring item information and operation information on the basis of the project data, the device-monitoring item information having a description of the monitoring information according to a common format that is not dependent on the device, and the operation information having an association of a second calculation formula obtained by modifying the first calculation formula using the monitoring item of the project data, with a label attached to a result of operation of the second calculation formula.

2. A design support device comprising:
a project memory to store project data including device information that is information about a device, monitoring information that is information about a monitoring item and is linked to the device information, and a communication system representing a communication protocol for acquiring the monitoring item, the project data having information necessary to control the device, stored therein; and
device profile generation circuitry to generate a device profile including device-monitoring item information and protocol information on the basis of the project data, the device-monitoring item information having a description of the monitoring information according to a common format that is not dependent on the device, and the protocol information specifying a method of acquiring data of the monitoring item of the device-monitoring item information by the communication system.

3. The design support device according to claim 1, wherein
the project data further includes a communication system representing a communication protocol for acquiring the monitoring item, and
the device profile generation circuitry generates the device profile further including protocol information that specifies a method of acquiring data of the monitoring item in the device-monitoring item information by the communication system.

4. The design support device according to claim 3, wherein the protocol information further includes a method of acquiring a result of operation of the second calculation formula in the operation information.

5. The design support device according to claim 2, wherein the device profile generation circuitry generates the device profile including the protocol information that specifies a method of acquiring data of one of the monitoring items in the device-monitoring item information.

6. The design support device according to claim 2, wherein
the project data further includes information used to group the monitoring items, and
the device profile generation circuitry generates the device profile including the protocol information that specifies a method of collectively acquiring data of a plurality of the monitoring items grouped in the device-monitoring item information.

7. The design support device according to claim 1, wherein the device profile generation circuity displays a calculation formula setting screen on a display and generates the operation information according to contents set on the calculation formula setting screen, the calculation formula setting screen including a calculation formula display area in which a second calculation formula obtained by modifying the first calculation formula using the monitoring item in the project data is displayed, a label name setting field in which sets a label attached to a result of operation of the second calculation formula is set, and a storage area setting field in which a storage area storing the result of operation of the second calculation formula is set.

8. The design support device according to claim 7, wherein the device profile generation circuitry checks whether a monitoring item corresponding to an element constituting the first calculation formula is present in the project data, and displays the first calculation formula for which all the monitoring items corresponding to elements constituting the first calculation formula are present in the project data as the second calculation formula in the calculation formula display area.

9. The design support device according to claim 1, further comprising:
network analysis circuitry to acquire route information of the device connected via a network, and
a project data reader to communicate with the device using the route information and read project data held by the device.

10.-11. (canceled)

12. A non-transitory computer readable storage medium in which a design support program is stored, the design support program being configured to cause a computer to execute:
a procedure of storing project data including device information that is information about a device and monitoring information that is information about a monitoring item and is linked to the device information, the project data having information necessary to control the device, stored therein;
a procedure of storing specification data that is data in which a specification serving as a design guideline of a device profile is defined, and includes an operated monitoring item name defined by a first calculation formula; and
a procedure of generating a device profile including device-monitoring item information and operation information on the basis of the project data, the device-monitoring item information having a description of the monitoring information according to a common format that is not dependent on the device, and the operation information having an association of a second calculation formula obtained by modifying the first calculation formula using the monitoring item of the project data, with a label attached to a result of operation of the second calculation formula.

13. A non-transitory computer readable storage medium in which a design support program is stored, the design support program being configured to cause a computer to execute:
a procedure of storing project data including device information that is information about a device, monitoring information that is information about a monitoring item and is linked to the device information, and a communication system representing a communication protocol for acquiring the monitoring item, the project data having information necessary to control the device, stored therein; and
a procedure of generating a device profile including device-monitoring item information and protocol information on the basis of the project data, the device-monitoring item information having a description of the monitoring information according to a common format that is not dependent on the device, and the protocol information specifying a method of acquiring data of the monitoring item of the device-monitoring item information by the communication system.

14. The design support device according to claim 2, further comprising:
network analysis circuitry to acquire route information of the device connected via a network; and
a project data reader to communicate with the device using the route information and read project data held by the device.
